(19) United States
(12) Patent Application Publication
(10) Pub. No.: US 2005/0045867 A1
(43) Pub. Date: Mar. 3, 2005

(54) Nanoscale heterojunctions and methods of making and using thereof

(76) Inventors: Cengiz S. Ozkan, San Diego, CA (US); Sathyajith Ravindran, Riverside, CA (US); Roger Lake, Riverside, CA (US); Mihrimah Ozkan, San Diego, CA (US); Natan Portney, Riverside, CA (US)

Correspondence Address: Suzannah K. Sundby;Smith, Gambrell & Russell, Suite 800, 1850 M Street, N.W., Washington, DC, 20036, US

(21) Appl. No.: 10/695,775

(22) Filed: Oct. 30, 2003

Related U.S. Application Data
(60) Provisional application No. 60/422,811, filed on Oct. 30, 2002.

(51) Int. Cl. H01L 29/06; H01L 31/0328; H01L 21/00

(52) U.S. Cl. 257/12; 438/47; 438/105; 257/183

(57) ABSTRACT

Disclosed herein are nanoscale heterojunctions and methods of making and using thereof. The heterojunctions comprise at least one carbon nanotube with at least one nanostructure such as a quantum dot connected, immobilized, attached, or affixed thereto. The carbon nanotubes may be single walled, multi-walled, or a combination of both. The nanostructure is preferably a quantum dot such as a ZnS capped CdSe core. The carbon nanotube heterojunctions may be employed in various nanoscale electronics and optoelectronic devices and multilayered systems including light emitting diodes, single electron transistors, spintronic devices, field emission flat panel displays, vacuum microelectronic sources, biosensors, random access memories, spin valves, and the like.

### CROSS REFERENCE TO RELATED APPLICATIONS

This application claims the benefit of U.S. Provisional Patent Application No. 60/422,811, filed 30 Oct. 2002, listing Cengiz S. Ozkan as the inventor, which is herein incorporated by reference in its entirety.

### BACKGROUND OF THE INVENTION

1. Field of the Invention

The present invention generally relates to nanoscale heterojunctions and methods of making and using thereof.

2. Description of the Related Art

The unique electrical, mechanical, and chemical properties of carbon nanotubes have made them intensively studied materials in the field of nanotechnology. See Dai, H. J. (2002) Surface Sci. 500:218; Ajayan, P. M. (1999) Chem. Rev. 99:1787; Yakobson, B. I. and Smalley, R. E. (1997) Am. Sci. 85:324; and Dresselhaus, M. S., et al. (1996) Science of Fullerenes and Carbon Nanotubes; Academic Press, New York, which are herein incorporated by reference. A number of device applications of these nanoscale materials have been envisioned. See Lee, S. M. and Lee, Y. H. (2000) Appl. Phys. Lett. 76:2877; Dai, H. J., et al. (1996) Nature 384:147; Wong, S. S., et al. (1998) J. Am. Chem. Soc. 120:603; Wong, S. S., et al. (1998) Nature 394:52; Wong, S. S., et al. (1998) J. Am. Chem. Soc. 120:8557; Nishijima, H., et al. (1999) Appl. Phys. Lett. 74:4061; Peng, H. Q., et al. (2001) Nano Lett. 1:625; Wang, Q., et al. (2002) Electrochem. Solid State Lett. 5:A188; Maurin, G., et al. (2001) Nano Lett. 1:75; Britto, P. J., et al. (1996) Bioelectrochem. Bioenerg. 41:121; Davis, J. J., et al. (1997) J. Electroanal. Chem. 440:279; Campbell, J. K., et al. (1999) J Am. Chem. Soc. 121:3779; Nugent, J. M., et al. (2001) Nano Lett. 1:87; Azamian, B. R., et al. (2002) J. Am. Chem. Soc. 124:12664; Wu, F. H., et al. (2002) Electrochem. Commun. 4:690; Wang, J. X., et al. (2002) Anal. Chem. 74:1993; and Kong, J., et al. (2000) Science 287:622. Single-walled carbon nanotubes (SWCNTs) and multi-walled carbon nanotubes (MWCNTs) under special conditions have been shown to possess ballistic conduction behavior, which makes them attractive candidates for field emission devices. See White, C. T. and Todorov, T. N. (1998) Nature 393:240; Frank, S., et al. (1998) Science 280:1744; Berger, C., et al. (2002) Appl. Phys. A-Mat. Sci. Process 74(3):363; Saito, Y., et al. (1998) Appl. Phys. A-Mat. Sci. Process 67:95; Chen, Y., et al. (2000) Appl. Phys. Lett. 76:2469; Hong, W. K., et al. (2000) Jpn. J Appl. Phys. Pt. 239:L925; and Chhowalla, M., et al. (2001) J. Appl. Phys. Lett. 79:2079. SWCNTs indicate either metallic or semiconductor behavior depending on their chirality and radial dimension. See Odom, T. W., et al. (1998) Nature 391:59; White, C. T. and Mintmire, J. W. (1998) Nature 394:29; and Martel, R., et al. (1998) Appl. Phys. Lett. 73:2447. Although the electronic properties of MWCNTs are less well known, they have been shown to exhibit either metallic or semiconducting properties depending on their outermost shell. See Yosida, Y. (1999) J. Phys. Chem. Solids 60:1; Suzuki, S., et al. (2002) Surf Rev. Lett. 9:431; Li, J., et al. (2002) Appl. Phys. Lett. 81:910; Jang, J. W., et al. (2002) Solid State Commun. 122:619; and Tekleab, D., et al. (2000) Appl. Phys. Lett. 76:3594. The inter-shell interactions in a MWCNT are weak, therefore, electrical transport is confined to the outermost shell. It has been shown recently that it is possible to manipulate the electrical properties of a MWCNT by using current induced oxidation to systematically breakdown the outermost shells layer by layer. See Radosavljevic, M., et al. (2001) Phys. Rev. B 6424:1307; Collins, P. C., et al. (2001) Science 292:706; and Collins, P. G., et al. (2001) Phys. Rev. Lett. 86:3128. This opens up the possibility of selecting the tube with the desired electrical property. In addition, doping and introduction of defects or distortion in the CNTs have also been utilized for manipulating their energy band structure. See Tombler, T. W., et al. (2000) Nature 405:769. The versatile electrical properties of CNTs make them promising candidates for nanoscale electronic devices, especially transistors. See Fan, S. S., et al. (1999) Science 283:512; Lee, Y. H., et al. (2001) Adv. Mater. 13:1371; Tans, S. J., et al. (1998) Nature 393:49; Li, J., et al. (1999) Nature 402:253; Yao, Z., et al. (1999) Nature 402(6759):273; Ahlskog, M., et al. (2000) Appl. Phys. Lett. 77:4037; Zhou, C. W., et al. (2000) Science 290:1552; Ahlskog, M., et al. (2001) J. Low Temp. Phys. 124:335; Rosenblatt, S., et al. (2002) Nano Lett. 2:869; and Fuhrer, M. S., et al. (2000) Science 288:494. In most of the previous work on CNT based nanoscale transistors, the control over the electrical properties of the devices have been limited. In addition, these devices relied on overlapping CNTs for forming junctions, which introduces local bending. Distortions due to bending leads to an electron transport barrier results in reduced electrical conductance of nanotube systems.

Semiconducting nanomaterials have been conjugated with carbon nanotubes to create heterojunctions. Quantum dots (QDs), which are semiconducting nanocrystals, possess size tunable electronic and optical properties resulting from quantum confinement. See Brus, L. (1991) Appl. Phys. A 53:465; and Alivisatos, A. P. (1996) J. Phys. Chem. 100:13226. QDs offer high resistance to photo bleaching thus making them attractive materials for optoelectronics and in-vivo biosensing applications. See Banerjee, S. and Wong S. S. (2002) Nano Lett. 2:195; Haremza, J. M., et al. (2002) Nano Lett. 2:1253; and Chan, W. C. W. and Nie S. M. (1998) Science 281:2016. The development of carbon nanotube-quantum dot (CNT-QD) heterojunctions have recently received interest resulting from developments in chemical modification of CNTs. Due to their chemical inertness, the modification of CNTs were typically carried out with non-covalent functionalization. See Chen, R. J., et al. (2001) J. Am. Chem. Soc. 123:3838; Erlanger, B. F., et al. (2001) Nano Lett. 1:465; Mattson, M. P., et al. (2000) J. Mol. Neurosci. 14:175; O'Connell, M. J., et al. (2001) Chem. Phys. Lett. 342:265; Star, A., et al. (2001) Angew. Chem. Int. Ed. 40(9):1721; Shim, M., et al. (2001) J. Am. Chem. Soc. 123:11512; and Banerjee, S. and Wong, S. S. (2002) Nano Lett. 2:49. Covalent chemical modification it directly interacts with the graphitic lattice structure of the CNTs. See Bahr, J. L. and Tour, J. M. (2002) J. Mater. Chem. 12:1952. The first direct covalent functionalization method was based on acid oxidation of CNT's, which results in carboxyl groups at the tips and other high defect density sites. See Liu, J., et al. (1998) Science 280:1253; and Rinzler, A. G., et al. (1998) Appl. Phys. A-Mat. Sci. Process 67:29. Several other methodologies included fluorination, electrophilic addition of chloroform, esterification, proteins and nucleic acids functionalization via diimide-activated amidation, electrochemical reduction of aryl diazonium salts and electrochemical oxidation of aromatic amines. See Mickelson, E. T., et al. (1998) Chem. Phys. Lett. 296:188; Tagmatarchis, N., et al. (2002) Chem. Commun. 18:2010; Hamon, M. A., et al. (2002) Appl. Phys. A-Mat. Sci. Process 74:333; Huang, W. J., et al. (2002) Nano Lett. 2:311; Pompeo, F. and Resasco, D. E. (2002) Nano Lett. 2:369; Nguyen, C. V., et al. (2002) Nano Lett. 2:1079; Bahr, J. L., et al. (2001) J. Am. Chem. Soc. 123:6536; and Kooi, S. E., et al. (2002) Angew. Chem. Int. Ed. 41:1353. Covalent modifications of carbon nanotubes with metal colloids (for low resistance ohmic contacts) and semiconducting quantum dots (for light emitting diodes) have also been reported. See Azamian, B. R., et al. (2002) Chem. Commun. 4:366. The resulting structures from these studies indicated either undesired sidewall reactions leading to clustering of the QDs. See Banerjee, S. and Wong S. S. (2002) Nano Lett. 2:195. It has been reported that the conjugation of single QDs at the ends of individual SWCNT when the length of the CNT is less than 200 nm, whereas for longer tubes, sidewall conjugations were reported. Sidewall functionalization adversely affects the electrical conductivity and other electronic properties of the CNT. See Bahr, J. L. and Tour, J. M. (2002) J. Mater. Chem. 12:1952. This is because the sidewall carbon lattices are disrupted resulting in the generation of defects along the sidewalls. Such multiple functionalizations are yet to find practical applications in nanoelectronics. In addition, providing contacts to a single QD for device fabrication is still one of the major challenges for nanoscale device integration. Electron beam lithography can be used to fabricate device features such as interconnects with critical dimensions as small as 10 nm, which is still larger, compared to the size of a single QD.

Thus, a need exists for carbon nanotube junctions that maintain the chemical, electrical, and physical properties of the carbon nanotubes and other nanostructures.

### SUMMARY OF THE INVENTION

The present invention generally relates to nanoscale heterojunctions.

In some embodiments, the present invention provides a heterojunction comprising at least one carbon nanotube and at least one nanostructure connected, immobilized, attached, or affixed thereto.

In some embodiments, the carbon nanotube is a single walled carbon nanotube having a length of about 20 nm to about 2000 nm, preferably about 20 nm to about 1000 nm, more preferably about 20 nm to about 500 nm, even more preferably about 20 nm to about 250 nm, and most preferably about 20 nm to about 100 nm. In some embodiments, the carbon nanotube is a multi-walled carbon nanotube having a length of about 40 nm to about 4000 nm, preferably about 40 nm to about 2000 nm, more preferably about 40 nm to about 1000 nm, even more preferably about 40 nm to about 500 nm, and most preferably about 40 nm to about 250 nm.

In some embodiments, the nanostructure is selected from the group consisting of photoactive molecules, photonic molecules, inorganic ions, inorganic molecules, magnetic ions, magnetic molecules, metallic ions, metallic molecules, metallic colloids, metal oxide molecules, polymers, aptamers, haptens, radioactive molecules, fluorophores, chromophores, chemiluminescent molecules, nanowires, nanofibers, quantum dots, nucleotides, nucleic acid molecules, polynucleotides, amino acids, peptides, polypeptides, proteins, and peptide nucleic acids. In some preferred embodiments, the nanostructure is a quantum dot or a quantum cluster comprising a plurality of quantum dots. Preferably, the quantum dot is ZnS capped CdSe, CdSe, or TiO₂.

In some embodiments, the heterojunction of the present invention comprises one carbon nanotube having one nanostructure connected, immobilized, attached, or affixed to one end of the carbon nanotube.

In some embodiments, the heterojunction of the present invention comprises one carbon nanotube having two nanostructures connected, immobilized, attached, or affixed to each end of the carbon nanotube.

In some embodiments, the heterojunction of the present invention comprises at least two carbon nanotubes having a nanostructures connected, immobilized, attached, or affixed to one end of each of the carbon nanotubes.

In some embodiments, the present invention provides methods for making the heterojunctions of the present invention which comprises oxidizing the ends of the carbon nanotube, placing at least one amine group on the nanostructure, and coupling at least one end of the carbon nanotube with the nanostructure. In some embodiments, oxidizing the ends of the carbon nanotube comprises refluxing the carbon nanotube in an acid such as nitric acid. In some embodiments, the nanostructure has a ZnS shell or coating and placing at least one amine group on the nanostructure comprises reacting the nanostructure with 2-aminoethanethiolhydrochloride. In some embodiments, coupling the end of the carbon nanotube with the nanostructure comprises adding 1-ethyl-3-(3-dimethylaminopropyl)carbodiimide HCL in the presence of N-hydroxysuccinimide to form a sulfosuccinimidyl intermediate that is capable of forming an amide bond with the amine group on the nanostructure.

In some embodiments, the present invention provides nanodevices comprising at least one heterojunction of the present invention. The nanodevices of the present invention may further comprise at least one nanostructure selected from the group consisting of photoactive molecules, photonic molecules, inorganic ions, inorganic molecules, magnetic ions, magnetic molecules, metallic ions, metallic molecules, metallic colloids, metal oxide molecules, polymers, aptamers, haptens, radioactive molecules, fluorophores, chromophores, chemiluminescent molecules, nanowires, nanofibers, quantum dots, nucleotides, nucleic acid molecules, polynucleotides, amino acids, peptides, polypeptides, proteins, and peptide nucleic acids. In some embodiments, the nanodevice is a transistor, a light emitting diode, an inverter, a resistors, a capacitors, an interconnect, or a biosensor.

It is to be understood that both the foregoing general description and the following detailed description are exemplary and explanatory only and are intended to provide further explanation of the invention as claimed. The accompanying drawings are included to provide a further understanding of the invention and are incorporated in and constitute part of this specification, illustrate several embodiments of the invention and together with the description serve to explain the principles of the invention.

### DESCRIPTION OF THE DRAWINGS

This invention is further understood by reference to the drawings wherein:

FIG. 1 is a schematic of the conjugation of MWCNTs to ZnS capped CdSe nanocrystals. Part A shows grown MWCNTs (I) that were oxidized by refluxing it in HNO₃ at 130° C. for 24 hours to open the ends and create carboxylic group terminating MWCNTs (II). Part B shows ZnS capped CdSe QDs in chloroform (III) agitated with AET to stabilize them in aqueous PBS (IV). Part C shows heterojunctions of CNT-QDs that were synthesized by using a zero length cross linker EDC.

FIG. 2A shows that prior to capping the ZnS surface with AET the QDs are in the heavier organic phase.

FIG. 2B shows that after the aminoethane thiol treatment, the QDs go into the lighter aqueous phase.

FIG. 3A shows an SEM image of water-soluble QD-NH₂, wherein the aggregation is due to the evaporation of the solvent prior to the SEM imaging.

FIG. 3B shows an SEM image of water-soluble QD-NH₂, wherein the QDs are well dispersed.

FIG. 4A shows an SEM image of MWCNT tips conjugated to QDs by the EDC coupling procedure. Several separate conjugations are shown.

FIG. 4B shows one MWCNT conjugated to a QD.

FIG. 4C shows another MWCNT conjugated to QDs

FIG. 4D shows a MWCNT with a smaller diameter and with a smaller group of QDs attached to its end.

FIG. 5A shows an SEM image of MWCNT before conjugation with QD-NH₂: The MWCNT is free from any particle like features.

FIG. 5B is a TEM image of an oxidized MWCNT clearly indicating the removal of the cap.

FIG. 5C is an SEM image of a CNT-QD heterostructure with QDs at both the ends of the MWCNT.

FIG. 5D shows a MWCNT bundle with QDs only at the ends.

FIG. 6A is a TEM image of a long MWCNT (about 4 μm long and about 40 nm in diameter) with QDs at the end. Regions marked 1, 2, 3, and 4 on the MWCNT indicate filling of the MWCNT possibly with QDs.

FIG. 6B is a cluster of the QDs at the tip of the MWCNT at higher magnification.

FIG. 6C is a magnified region of FIG. 6A that shows that material is inserted into the MWCNT.

FIG. 7A is an SEM image of MWCNT across interconnect lines on a Si/SiO₂ substrate. Due to the hydrophilic nature of the oxidized CNT tips, the CNTs self assemble themselves across the metal lines.

FIG. 7B is an SEM image of a MWCNT bundle with a QD at the tip oriented across the electrode lines.

FIG. 8A shows a TEM image of a quantum dot cluster at the end of a carbon nanotube. The material appearing on the sidewalls were confirmed to be impurities using EDS analysis.

FIG. 8B shows the quantum dot cluster of FIG. 8A imaged at a higher magnification.

FIG. 9 shows FTIR spectra of oxidized MWCNTs (blue) and MWCNT-QD conjugates (red). Absorption peaks are observed at 1644 cm⁻¹, 1704 cm⁻¹ and 3403 cm⁻¹ (A, B, and C) in the FTIR spectra for oxidized tubes. New peaks develop at 1653 cm⁻¹, 2977 cm⁻¹ and 3314 cm⁻¹ (D, E, and F) in the FTIR spectra of MWCNT-QD conjugates, indicating formations of MWCNT-QD conjugates via amide bond formation.

FIG. 10 is a TEM image of a QD cluster between two MWCNTs. Inset A shows the heterojunction at a higher magnification. The image clearly shows that there are two MWCNTs which are embedded in the QD cluster. Inset B shows a magnified image of the MWCNT. The locations of the spot EDS analyses obtained from this cluster are marked by numbers as shown in FIGS. 11A, 11B, and 11C.

FIG. 11A shows an EDS spectrum from (Region 1 in FIG. 10) the QD cluster obtained with electron beam focused to spot size of about 10 nm in diameter. Strong Cd, Se, Zn, and S signals are consistent with a QD cluster composed of ZnS capped CdSe nanoparticles.

FIG. 11B shows an EDS spectrum from (Region 2 in FIG. 10) the MWCNT-QD junction.

FIG. 11C shows an EDS spectrum of (Region 3 in FIG. 10) the MWCNT alone, note the absence of Cd and Zn peaks.

FIG. 12 shows a convergent beam electron diffraction pattern from the QD cluster. Inset A shows individual QDs in a QD cluster (at the end of a MWCNT) tend to order themselves. Inset B shows electron diffraction from the QD cluster.

FIG. 13A shows individual QDs in a cluster ordered in a pseudo-hexagonal close packed array.

FIG. 13B shows HRTEM image of QDs in a cluster at high magnification.

FIG. 14A shows ZnS capped CdSe at the ends of a CNT.

FIG. 14B shows ZnS capped CdSe nanocrystals coupled to a CNT.

FIG. 15 shows exemplary electrical contacts in a nanodevice of the present invention.

### DETAILED DESCRIPTION OF THE INVENTION

The present invention provides heterojunctions and making and using thereof. In preferred embodiments, the heterojunctions are quantum dot (CNT-QD) heterojunctions. The present invention provides methods of making the CNT-QD heterojunctions, and nanodevices comprising the CNT-QD heterojunctions.

The present invention provides methods for making heterojunctions such as carbon nanotube-quantum dot (CNT-QD) heterojunctions which comprises using an ethylene carbodiimide coupling (EDC) procedure. In preferred embodiments, the present invention provides methods for the controlled synthesis of making the CNT-QD heterojunctions. The carbon nanotubes (CNTs) may be single-walled carbon nanotubes (SWCNTs) or multi-walled carbon nanotubes (MWCNTs). As used herein, CNT is used to refer to SWCNTs, MWCNTs, or both. The CNTs of the CNT-QD heterojunctions may be all SWCNTs, all MWCNT, or a mixture of both. The CNT-QD heterojunctions of the present invention may be used to connect, attach, or fix at least one CNT to a nanostructure or a substrate such as those known in art. See e.g Terrones, M., et al. (1997) Nature 388:52; Rao, C. N. R., et al. (1998) Chem. Commun. 1525-1526; and Ren, Z. F., et al. (1998) Science 282:1105-1107, which are herein incorporated by reference. The CNT-QD heterojunctions of the present invention may further include at least one additional nanostructure connected, immobilized, attached, or affixed thereto. As used herein, a “nanostructure” or “nanodevice” is an assemblage of atoms and/or molecules comprising structural, functional and/or joining elements, the elements having at least one characteristic length (dimension) in the nanometer range.

Also as used herein, the term “quantum dot” and “nanocrystal” are synonymous and refer to any particle with size dependent properties (e.g., chemical, optical, and electrical properties) along three orthogonal dimensions. A QD can be differentiated from a quantum wire and a quantum well, which have size-dependent properties along at most one dimension and two dimensions, respectively. It will be appreciated by one of ordinary skill in the art that QDs can exist in a variety of shapes, including but not limited to spheroids, rods, disks, pyramids, cubes, and a plurality of other geometric and non-geometric shapes. While these shapes can affect the physical, optical, and electronic characteristics of QDs, the specific shape does not bear on the qualification of a particle as a QD. A QD typically comprises a “core” of one or more first materials and can optionally be surrounded by a “shell” of a second material. Although thiol stabilized ZnS capped CdSe QDs containing amine terminal groups (QD-NH₂) conjugated with acid treated MWCNTs ranging from 400 nm to 4 μm in length are exemplified herein, other suitable QDs such as CdSe, TiO₂, and the like may be used according to the present invention. N-type QDs can be made by successful electron transfer from sodium biphenyl to the LUQCO (Lowest Unoccupied Quantum-Confined Orbital) of the nanocrystals. See Shim, M et al. (2000) Nature 407:981, which is herein incorporated by reference.

The CNTs of the present invention may be obtained from commercial sources or made according to methods know in the art. See e.g. U.S. patent application Publication Nos. 720020159943, 820020150524, 920020136683, 1220020127162, 1320020125470, 1520020098135, 1720020090331, and 1820020090330, which are herein incorporated by reference. The CNTs are p-type, but may be modified by doping or annealing. See Park, J., et al. Appl. Phys. Letts. 79(9): 1363, which is herein incorporated by reference. Micro-patterns of vertically aligned CNTs perpendicular to the substrate surface may be prepared by masking techniques, pre-patterning the substrate using e-beam lithography, and soft-lithography methods known in the art. See Fan, S. S., et al. (1999) Science 283:512; Huang, S., et al. (2000) J. Phys. Chem. B 104:2193-2196; and Huang, S., et al. (1999) J. Phys. Chem. B 103:4223-4227, which are herein incorporated by reference. CNTs may be directly patterned on Si—SiO₂ patterned substrate has been demonstrated. See Wei, B. Q., et al. (2002) Nature 416:495-496, which is herein incorporated by reference. CNTs may be horizontally patterned by a combination of e-beam lithography and thermal chemical vapor deposition (CVD) methods known in the art. See Kong, J., et al. (1998) Nature 395:878-881, which is herein incorporated by reference.

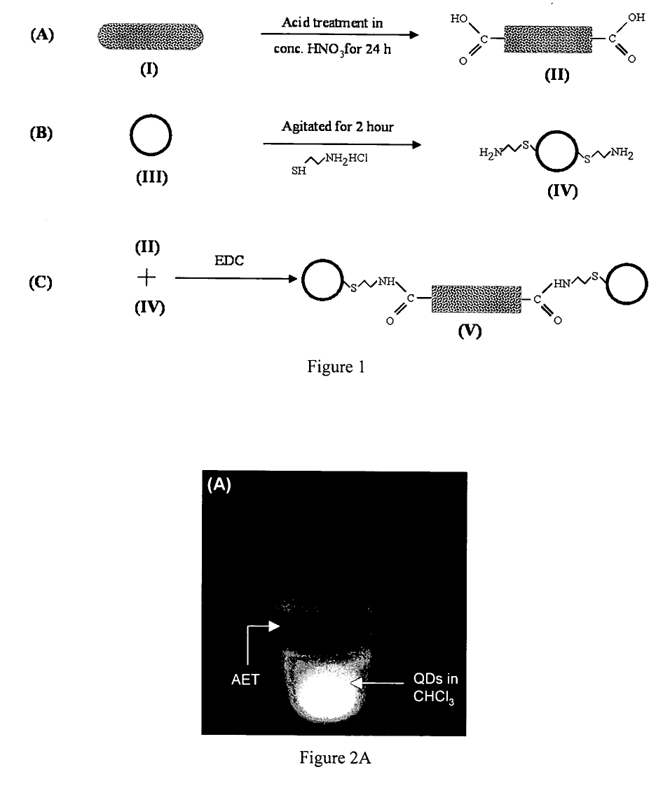

The present invention provides heterostructures that comprise two or more different nanostructures such as at least one CNT and at least one QD. As used herein, the terms “heterostructure” and “heterojunction” are used interchangeably to refer to two or more inorganic and/or organic nanostructures that are joined, linked, conjugated or operably connected together. The heterostructures comprising QDs of the present invention have high quantum yield and long life and are well-dispersed individual units that facilitate monitoring real time fluidic behavior and fluorescent imaging in biosystems. The present invention provides methods of making CNT-QD heterojunctions with controlled conjugation of QDs, such as water-stabilized, amine-terminating, ZnS coated CdSe QDs (QD-NH₂), to acid treated ends of CNTs, preferably MWCNTs. See Ravindran S., et al. (2003) Nano Lett. 3(4):447-453, which is herein incorporated by reference. FIG. 1 illustrates the procedure used in the synthesis of the heterojunctions.

Grown MWCNTs (Nanostructured & Amorphous Materials, Inc., Los Alamos) were oxidized by refluxing at 130° C. in nitric acid for 24 hours. It has been reported that MWCNTs are oxidized at a slower rate as compared to SWCNTs. See Rao, A. M., et al. (2001) Phys. Rev. Lett. 86:3895. Additionally, the tips of MWCNTs, which have the highest defect sites, get oxidized first. The use of nitric acid reflux oxidizes MWCNTs mildly and preferentially at their ends. The oxidations at the CNT ends are highly localized and therefore do not result in appreciable changes to the electrical properties of the CNTs. The oxidations at the CNT ends change the character at the ends of the CNTs from hydrophobic to hydrophilic.

The acid treated CNTs were then washed with distilled water several times and finally vacuum filtered using a 0.1 μm polycarbonate filter. The filtered CNT cake was dried by heating at 150° C. for 24 hours. The acid treatment, apart from introducing acid groups at the end of the CNT, oxidizes the graphitic impurities present along with the CNTs. Prolonged oxidation with sonication attacks the defect sites and breaks the CNTs. After oxidation, the CNTs are shorter and are left with the carboxylic groups that impart a hydrophilic nature and facilitate further functionalization. ZnS capped CdSe QDs (Evident Technologies, Inc., NJ) were used in the functionalization of the MWCNTs. ZnS coating over the CdSe core improves the quantum yield by passivating the surface dangling bonds (carrier trap sites) and also eliminates the toxic nature of the CdSe core, thereby enabling them for use in biosystems. See Brus, L. (1991) Appl. Phys. A 53:465; Dabbousi, B. O., et al. (1997) J. Phys. Chem. B 101:9463; and Hines, M. A. and Gnyotsionnest, P. (1996) J. Phys. Chem. 100:468. Thus, QDs having a ZnS coating over a CdSe core are preferred, however other suitable QDs and nanostructures known in the art may be used.

To prepare water-stabilized QDs (QD-NH₂), ZnS capped CdSe nanocrystals were suspended in chloroform by sonication for 30 minutes. Equal volumes of 1.0 M 2-aminoethane thiol hydrochloride (AET) were added to this QD solution. This resulted in a two-phase mixture with the aqueous aminoethane thiol forming an immiscible layer above the organic chloroform-QD suspension. The mixture was stirred vigorously on a magnetic plate for 4 hours after which it was allowed to settle for a few minutes. Phosphate buffer saline (PBS, pH=7.5) was added to the solution at a 1:1 volume ratio which was then mixed again in a vortex mixer for an hour. The water stabilized QDs were separated from AET by centrifuging and resuspending in PBS two times. When ZnS capped CdSe QDs were reacted with AET, the mercapto group in the thiol bonded to the Zn atoms and the amine groups rendered the QDs hydrophilic, in addition to facilitating further functionalization possibilities. FIGS. 2A and 2B depict the situation before and after treating the QDs with AET. The observation that QDs are observed in the aqueous phase confirms the synthesis of water soluble QDs.

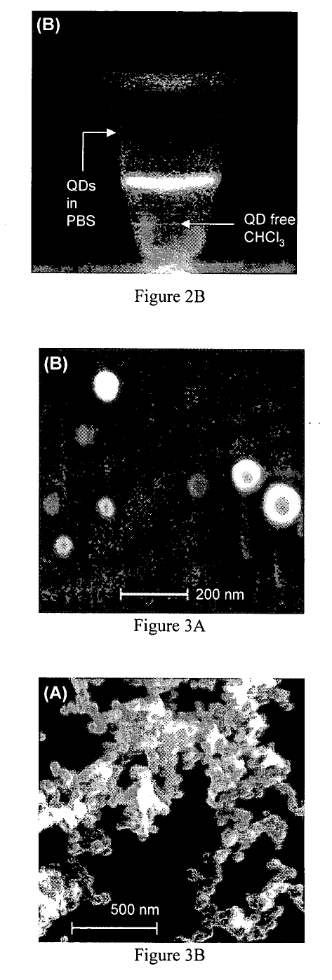

The aqueous phase containing the QD-NH₂ was extracted for use in the EDC reaction. SEM images of the water stabilized QD-NH₂ are shown in FIG. 3(a) and (b). The clustering in FIG. 3(a) is due to solvent evaporation. FIG. 3(b) image at high magnification indicates the well-dispersed QDs. Sonication of the water-soluble QDs resulted in undesirable aggregation of the QDs which may be due to the breaking of the electrostatic mercapto bond from the Zn atoms of the ZnS cap on the CdSe QD.

For the CNT-QD heterostructures, a two step coupling procedure using 1-ethyl-3-(3-dimethylaminopropyl) carbodiimide HCl (EDC, Pierce Chemicals, Inc., Rockford, Ill.) in the presence of N-hydroxysuccinimide (sulfo-NHS, Pierce Chemicals, Inc., Rockford, Ill.), and the reaction was carried out in PBS. Here, EDC reagent activates the terminal carboxylic groups of the CNTs forming a highly reactive o-acylisourea intermediate, which undergoes a rapid hydrolysis to form the acid again. However, in the presence of sulfo-NHS, a more water soluble sulfo-succinimidyl intermediate is formed. This intermediate readily undergoes nucleophilic substitution with primary amines on the QD surface forming amide linkages.

The EDC reaction was carried out for 8 hours at 50° C. under continuous mixing.

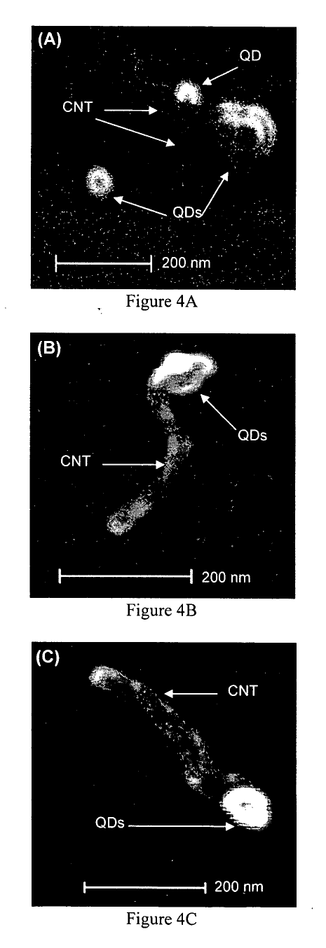

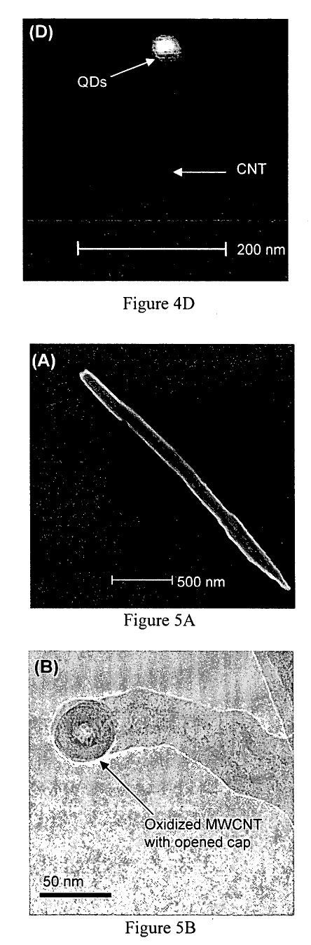

Characterization of the heterostructures was done using scanning electron microscopy and transmission electron microscopy. A drop of the reaction mixture containing the CNT-QD complexes was placed on a silicon chip and dried in a vacuum desiccator. FIGS. 4A-4D are SEM images of the CNT-QD conjugates. Sidewall functionalizations were absent because of the mild oxidation condition. The length of the MWCNTs in FIGS. 4A-4D are all less than 400 nm. The ends of the oxidized MWCNTs produce multiple carboxylic groups at their ends which results in the conjugation of multiple QDs at the ends. Since the size of the QD cluster is ideal for providing electrical contacts in nanodevices, the present invention also provides QD clusters that may be used as an electrical contact in a nanodevice.

FIG. 5A is an SEM image of MWCNTs before the EDC reaction. The CNT is free from any particle like features before modification, suggesting successful functionalization of MWCNT with QDs. Similarly, FIG. 5B depicts a TEM image of oxidized MWCNT with opened cap prior to QD conjugation. As shown in FIGS. 5C and 5D, conjugation of the QDs is specific to the CNT ends even for MWCNTs as long as about 600 nm to about 4 μm, as the QDs are observed only at the CNT ends. This specific conjugation at the CNT ends indicates the highly selective end functionalization of the CNTs. The rough appearance of the MWCNT is due to excess gold sputtering resulted during SEM sample preparation. All samples were prepared by drying a drop of MWCNTs (or CNT-QD) in ethanol over silicon substrates.

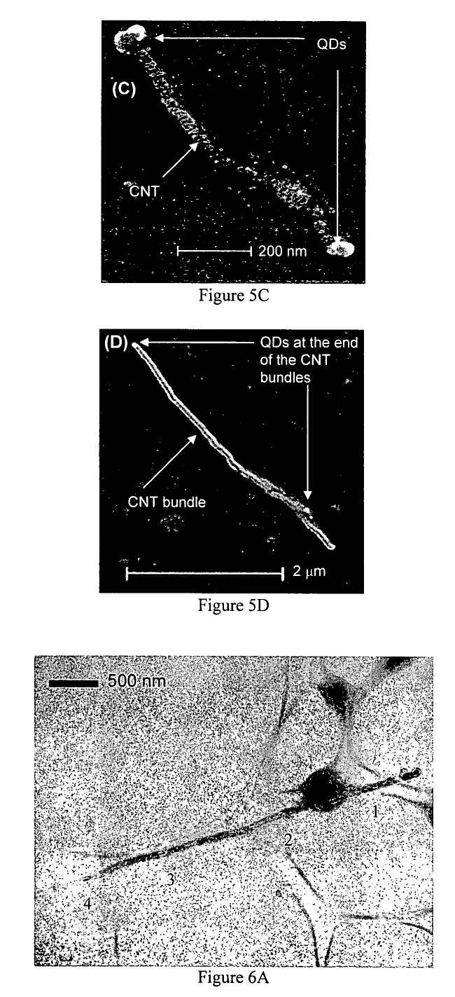

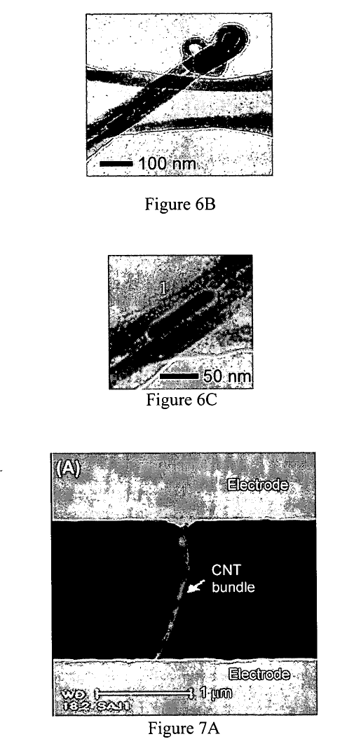

Further evidence for absence of side wall functionalization is provided by transmission electron microscopy as shown in FIG. 6. The TEM image in FIG. 6A shows a MWCNT with QDs at its ends. FIG. 6B is an image of the MWCNT end at higher magnification. Regions marked 1, 2, 3, and 4 in FIG. 6A show that material was inserted into the MWCNT (magnified in FIG. 6C). No evidence of sidewall functionalization was observed.

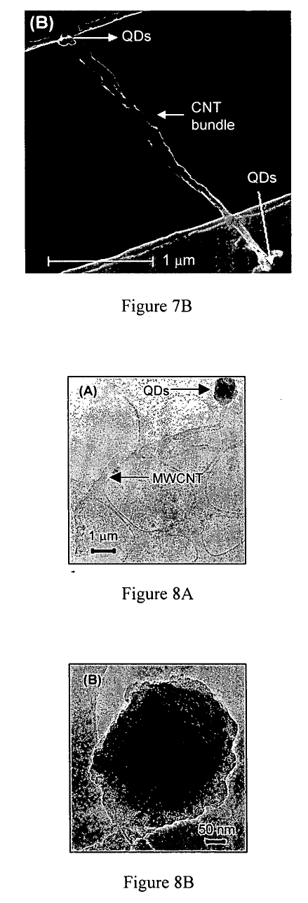

When employed in a nanodevice, the heterojunctions of the present invention may be arranged or aligned using methods known in the art. When acid treated CNTs suspended in distilled water were dispersed on a silicon substrate containing the hydrophilic aluminum interconnects (due to the thin native oxide layer), the hydrophilic ends of the CNTs self assemble themselves. FIG. 7A shows an SEM image of a grown MWCNT lying across the metal lines, and FIG. 7B is an SEM image of a MWCNT bundle conjugated with QDs at the ends across the metal lines.

Since the heterojunctions of the present invention are formed with oxidized MWCNTs which have carboxyl groups at both ends, the present invention provides at least three different heterojunction configurations, which are (1) at least one QD at one end of at least one MWCNT (MWCNT-QD), (2) at least one QD at each of the ends of at least one MWCNT (QD-CNT-QD) and (3) and at least one QD sandwiched between two or more MWCNTs.

MWCNTs were purchased from Nanostructured & Amorphous Materials, (Los Alamos, N. Mex.) and their diameters were about 40 nm to about 70 nm. Mild oxidation of the CNTs was carried out by refluxing them in HNO₃ for 24 hours so that the tips of the MWCNTs were oxidized. QDs used were ZnS capped cadmium CdSe nanostructures dispersed in toluene (Evident Technologies, New York). The ZnS capping passivates the quenching effect of the uncoordinated atoms on the surface of CdSe nanocrystals and enhances their photoluminescence (PL). See Myung, N., et al. (2002) Nano Lett. 2:1315; Ding, Z., et al. (2002) Science 296:1293; Schlamp, M. C., et al. (1997) J. Appl. Phys. 82:5837; Peng, X., et al. (1997) J. Am. Chem. Soc. 119:7019; and Danek, M., et al. (1996) Chem. Mater. 8:173, which are herein incorporated by reference. ZnS capping also provides a surface for further chemical functionalization. ZnS capped CdSe nanocrystals in toluene coated with a trioctylphosphine oxide (TOPO) layer were used as the starting material to prepare water-stabilized amine terminating QDs (QD-NH₂). Adding methanol washed off the TOPO stabilizing layer and rendered a cloudy suspension which was centrifuged and the pellet comprising QDs were washed with methanol 4 times to ensure the complete removal of toluene. 1.0 M 2-aminoethane thiol (AET) was added to resuspend the pellet and allowed to react for 2 hours. When ZnS capped CdSe QDs were reacted with AET, the mercapto group in AET bound to the Zn atoms and rendered the QDs hydrophilic, in addition to facilitating further functionalization possibilities. After the reaction, excess AET was washed off with a phosphate buffer (PBS, pH=6.47) using a centrifugal filter device (Millipore, Mass.). The water stabilized QDs obtained by the above procedure were used for the synthesis of MWCNT-QD heterostructures via the two-step coupling procedure using 1-ethyl-3-(3-dimethyl-aminopropyl) carbodiimide HCl (EDC, Pierce Chemicals, Inc., Tex.) in the presence of N-hydroxysuccinimide (sulfo-NHS, Pierce Chemicals, Inc., Tex.). The EDC reaction was carried out in PBS for 8 hours at 50° C. under continuous mixing. The heterostructures were characterized using scanning electron microscopy (SEM), transmission electron microscopy (TEM), Fourier transform infrared spectroscopy (FTIR) and energy dispersive spectroscopy (EDS).

FIG. 8 reveals the configuration of a heterojunction obtained by TEM using an FEI-Philips CM300 electron microscope equipped with a EDAX energy dispersive x-ray spectrometer (EDS). The estimated volume of this particular quantum dot cluster is about 0.06 μm³, which suggests that it (assuming about a 5 nm diameter for each QD) comprises more than about 400,000 nanostructures. The original size of the individual QDs are preserved and hence their quantum confinement is preserved as well. Sidewall functionalization on the CNTs was not observed. The composition of the QD clusters was analyzed by EDS with an effective probe size of about 10 nm in diameter. It was confirmed that the clusters comprised selenides and sulfides of Cd and Zn, respectively, in variable proportions. EDS analysis confirmed that there were no QDs on the side walls of the CNTs.

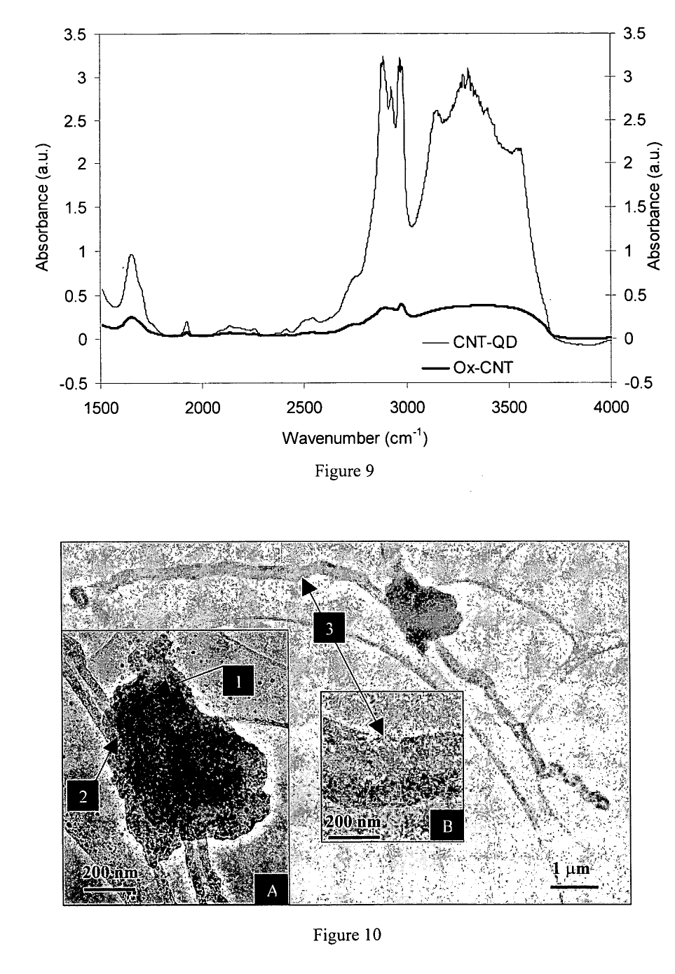

The MWCNT-QD conjugates were also characterized via FTIR spectroscopy, using an AgCl cell in a Bruker Equinox-55 FTIR spectrometer. FIG. 9 shows the FTIR spectra of oxidized MWCNTs (lower curve) and the CNT-QD conjugates (upper curve). With plain oxidized MWCNTs, absorption peaks were observed at 1644 cm⁻¹, 1704 cm⁻¹ and 3403 cm⁻¹ (peaks designated A, B, and C), which are characteristic of carboxylic and phenolic groups on acid treated MWCNTs. For the MWCNT-QD conjugates, new absorption peaks appeared at 1653 cm⁻¹, 2977 cm⁻¹ and 3314 cm⁻¹ (D, E, and F), which correspond to the C═O, C—H, and N—H stretching modes in amides, respectively. C—H and N—H peaks are higher than the amide C═O peak due to the presence of free QDs in the sample. A blue shift of carboxylic C═O stretch to amide C═O stretch and the appearance of C—H and N—H peaks indicate the formation of covalent MWCNT-QD conjugations, via amide bond formation.

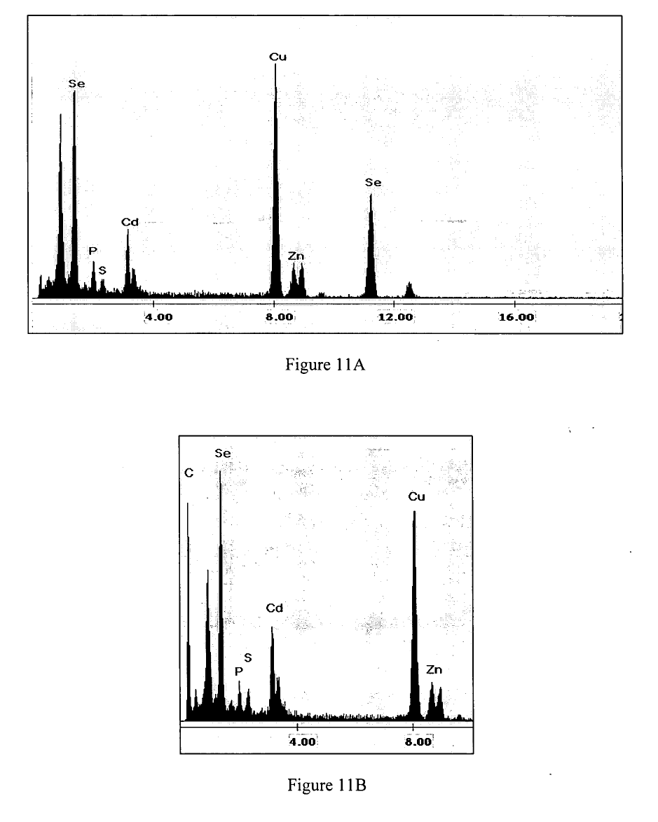

The formation of a CNT-QD-CNT heterojunction via fluidic processing is the least possible configuration among the three heterojunctions, and is the most desired configuration because of the ease of electrical probing via the two CNT ends, which can be achieved by patterning metal contacts using electron beam lithography. The TEM image of one such heterostructure is shown in FIG. 10. Two MWCNTs are attached to a QD cluster. Inset A of FIG. 10 shows the heterojunction at a higher magnification and the individual MWCNTs in the cluster. Regions 1, 2, and 3 are the regions at which the EDS analysis was conducted.

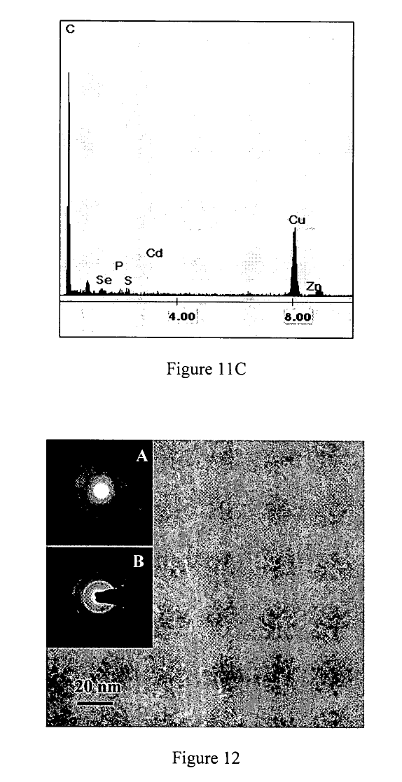

FIGS. 11A, 11B, and 11C shows the EDS spectra obtained from regions 1, 2, and 3, respectively in FIG. 10. The spot size used for all the EDS analysis is comparable in size with the lateral dimensions of individual QD, which provides localized information about the chemical composition of the cluster.

The Cu peaks present in all spectra arise from spurious x-ray radiation scattered by thick Cu grids, which support the specimen. The phosphorous peaks are due to the presence of remnants of the phosphate buffer. Strong Cd, Se, Zn, and S signals confirm that the cluster at the end of the MWCNT is made up of ZnS capped CdSe nanostructures. FIG. 11 is the EDS spectrum from the junction of the MWCNT and the QD cluster. A strong C peak at this location in addition to the peaks from CdSe and ZnS confirms the presence of a CNT. All EDS measurements were done over holes in the amorphous C support film thus reducing the contribution of the carbon support film to a minimum. FIG. 11 C is the EDS spectrum from the MWCNT alone at Region 3 showing that the MWCNT does not contain any other detectable elements except carbon.

Electron diffraction analysis confirmed that the QD clusters comprised hexagonal CdSe nanocrystals. Selected area electron diffraction (SAD) patterns obtained from an individual cluster of QDs (Inset B of FIG. 12) are consistent with the polycrystalline aggregate of randomly oriented hexagonal CdSe nanocrystals. This is also confirmed by the convergent beam electron diffraction (CBED) pattern in FIG. 12 which was obtained from an area of about 100 nm in diameter from the same cluster.

The apparent ordering of the QDs visualized by HRTEM imaging suggests that the individual nanostructures are held together in a two-dimensional pseudo-hexagonal close packing configuration that forms a mesoscale structure, but there is no mutual orientation of the atomic planes between adjacent QDs. This means that the regular order of Cd and Se atoms does not extend beyond the boundaries of each individual QD. The lack of ordering between adjacent QDs is probably due to the fact that each QD is coated with a very thin amorphous layer. The long-range mesoscale ordering of the QDs in the cluster is induced most probably by the need to obtain a minimal energy configuration and due to the presence of a possible amorphous coating. This allows the QDs to be arranged in a pattern governed by the requirement for minimum volume rather than the direction of possible strong bonding which would cause specific orientation between adjacent QDs, the lack of which as confirmed by the polycrystalline nature of the electron diffraction patterns.

QD arrays are artificial two-dimensional solids, with novel optical and electric properties. QDs can be tuned to incorporate different functional groups, e.g. COOH, NH₂, SH, and the like using methods known in the art. See Chan, W. C. W., (1998) Science 281:2016; and Cumberland, S. L. (2002) Chem. Mater. 14:1576-1584, which are herein incorporated by reference. The control of the properties is primarily by selection of the composition and the size of the individual QDs and secondly, through their packing. The packing factor may be a function of the potential of mean force of the medium in which the QDs are suspended. See Yethiraj, A. and van Blaaderen, A. A. (2003) Nature 421:513-517, which is herein incorporated by reference. The 2-D ordering of the nanostructures suggest different orientations between adjacent atomic layers.

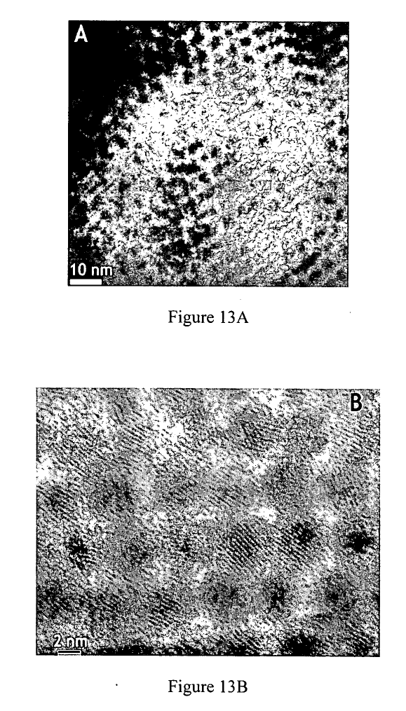

FIGS. 13A and 13B reveals the intimate nature of the ordered mesoscale structures. FIG. 13A shows individual QDs in a cluster ordered in a pseudo-hexagonal close packed array. FIG. 13B shows HRTEM image of QDs in a cluster at high magnification. The crystal planes of the individual QDs are randomly oriented with respect to each other. Each individual crystal is surrounded by amorphous coating which binds the QDs in a cluster. The individual QDs are ordered in a pseudo-hexagonal packing configuration. The individual particles represent single crystals and there is no mutual orientation of the crystal planes in adjacent crystals.

Therefore, the present invention provides QD clusters comprising individual ZnS coated CdSe nanoparticles ordered in a pseudo-hexagonal packing configuration with the crystal planes of each QD oriented in different directions. The QD cluster is covalently attached via an amide bond to the end of a MWCNT.

As disclosed herein, the controlled conjugation process may preserve the electronic properties of the CNTs and enable the assembly of nanodevices. The heterojunctions developed of the present invention are water-stabilized and thus can be easily functionalized further and then used as building blocks for various nanoscale electronic or optoelectronic devices and multilayered systems including light emitting diodes, single electron transistors, spintronic devices, field emission flat panel displays, vacuum microelectronic sources, biosensors, random access memories, spin valves, and the like. See Bonard, J. M., et al. (1998) Phys. Lett. 73:918-920; Fan, S. S., et al. (1999) Science 283:512; Murakami, H., et al. (2000) Appl. Phys. Lett. 76:1176-1178; Rao, A. M., et al. (2000) Appl. Phys. Lett. 76:3813-3815; Zhu, W., et al. (1999) Appl. Phys. Lett. 75:873-875; Wohlstadter, J. N., et al. (2003) Adv. Mater. 15:1184-1187; Rueckes, T., et al. (2000) Science 289:94-97; and Alphenaar, B. W., et al. (2001) J. Appl. Phys. 89:6863-6867, which are herein incorporated by reference.

The CNT-QD heterojunctions may be used in integrated circuits of nanodevices. Nanostructures, such as nanowires may be used to join two or more CNT-QD heterojunctions using methods known in the art such ass E beam lithography. In preferred embodiments, the nanodevices of the present invention comprise self-assembled nanoscale circuits that combine the CNT-QD heterojunctions disclosed herein with chemically mass-produced nanostructures such as nanocrystals and CNTs with biomimetic structuring schemes employing DNA recognition to assemble desired nanostructures from the bottom up.

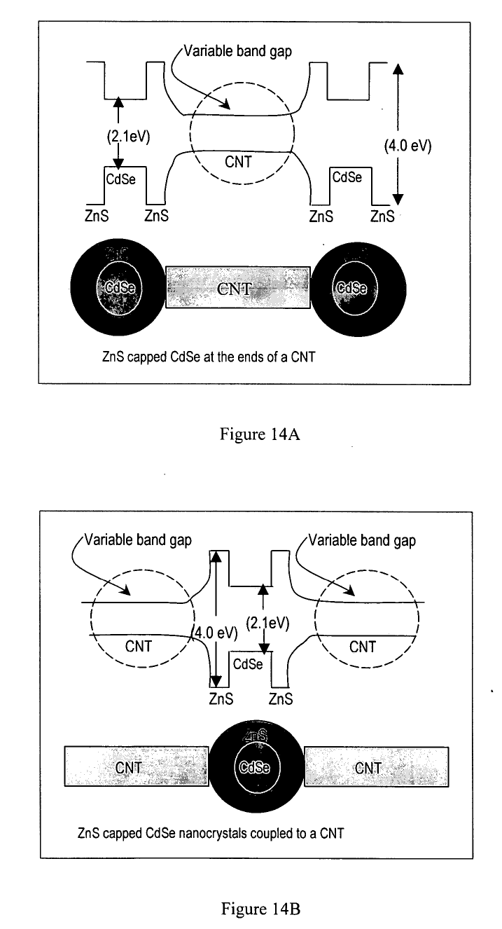

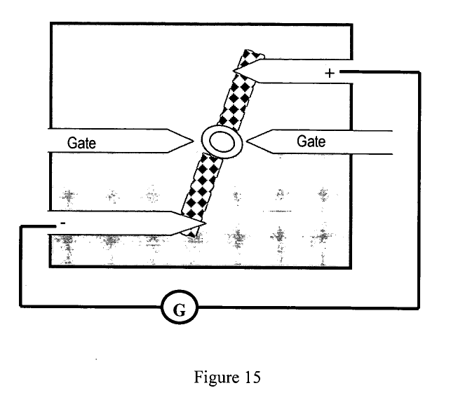

The CNT-QD heterojunctions of the present invention may be used as nanotransistors. Band diagrams of a nanotransistor of the present invention are shown in FIG. 14A and FIG. 14B. MWCNTs with large diameters possess metallic properties. Thus, a transistor formed out of a QD sandwiched between two metallic CNTs is expected to be similar to the single electron transistor developed by Cees Dekker. See Tans, S. J., et al. (1998) Nature 393:49, which is herein incorporated by reference. In preferred embodiments, a nanodevice of the present invention comprises at least one semiconducting nanostructure, such as a QD, between two metallic CNTs with the substrate as the gate electrode. Exemplary electrical contacts are shown in FIG. 15. By applying a voltage to the gate electrode, the QD can be switched from a conducting to an insulating state. SWCNTs can be metallic or semiconducting. Armchair SWCNTs are metallic with a conductivity of six orders higher than copper. Zig-zag and chiral tubes can be metallic or semi conducting and their band gaps can be engineered from about 0 to about 5 eV by (1) appropriate doping, e.g. metallic characteristics can be imparted using B or N doping, (2) inducing topological defects, or (3) mechanical deformation of CNT using pressure from a cantilever tip of an AFM, or by using an electric/magnetic field. See e.g. Tans, S. J., et al. (1998) Nature 393:49; Lee, R. S., et al. (2000) Phys. Rev. B 61:R4526; Smalley, et al. (2000) Phys. Rev. B 61:R10606; Dai, H., et al. (2000) Appl. Phys. Letts. 76:1597; and Dai, H., et al. (2000) Science 290:1552, which are herein incorporated by reference.

Nanodevices comprising the heterojunctions of the present invention may include a variety of nanostructures known in the art. CNTs may be grown in patterns on various substrates by methods known in the art such as a combination of lithography and thermal CVD techniques. The substrate may be prepatterned with a catalyst layer such as iron or nickel and the CNTs may be grown on the patterned substrate in a CVD reactor. Patterns of iron catalyst may be deposited on a silicon substrate by using physical mask in a thermal evaporator using methods known in the art. The resulting patterned substrates are then loaded in a horizontal flow CVD reactor.

Nanodevices comprising the heterojunctions of the present invention may include nanostructures, such as nanocrystals, conjugated DNA for detection and sensing. See Kim, J. H., et al. Nature Mater. (submitted), which is herein incorporated by reference. The nanodevices may include loop-DNA attached to organic fluorescent probes, inorganic nanocrystals, or both. See Pavski, V. and Le, X. C. (2003) Curr. Opi. Biotech. 14:65-73, which is herein incorporated by reference. The nanodevices may include molecular beacons (MBs) which are one of the unique deoxyribonucleicacid (DNA) and ribonucleicacid (RNA) probes that are at the “off” state when there is no complementary target sequence present and at the “on” state, when there is binding of the sequence that is under search. See Tyagi, S., et al. (1996) Nat. Biotechnol. 14:303-308; Tyagi, S., et al. (1998) Nat. Biotechnol. 16:49-53; Kostrikis, L. G., et al. (1996) Science 279:1228-1229; Sokol, D. L., et al. (1998) PNAS 96:11538-11543; and Knemeyer, J. P., et al. (2000) Anal. Chem. 72:3717-3724, which are herein incorporated by reference. The nanodevices may include a hybrid MB with inorganic fluorophore and organic quencher that exhibits improved stability against photobleaching. To this end, inorganic colloidal QDs after surface modification are attached to the 5′ end of MBs. See Alivisatos, A. P. (1996) J. Phys. Chem. 100:13226; Alivisatos, A. P. (1996) Science, 271:933-935; Chan, W. C. W. and Nie S. M. (1998) Science 281:2016; Niemeyer, C. M., (2001) Angew. Chem. Int. Ed. Engl. 40:4128-4158; Bruchez, M. Jr., et al. (1998) Science 281:2013-2015; Dabbousi, B. O., et al. (1997) J. Phys. Chem. B. 101:9463-9475; Dahan, M., et al. (2001) Opt. Lett. 26:825-827; Willard, D. M., et al. (2001) Nano Lett. 1:467-474; Wang, S., et al. (2002) Nano Lett. 2:817-822; Akerman, M. E., et al. (2002) PNAS USA 99:12617-12627; and Mitchell, G. P., et al. (1999) J. Am. Chem. Soc. 121:8122-8123, which are herein incorporated by reference. Mercaptoacetic acid treatment may be used to achieve mono-dispersed QDs in suspension. Next, surface modified QDs are resuspended in phosphate buffered saline (PBS) pH of 7.4. Through 1-ethyl-3-(3-dimethyl-aminopropyl) carbodiimide HCl (EDC) coupling, surface modified QDs can be conjugated to the MBs 5′ amine terminated DNA sequence, 5′(NH₂C₆H₁₂)-GCGA-CTTTGGGTTTGGGTTTC-TCGC, which has a (4-(4′-dimethylaminophenylazo)benzoic acid) (DABCYL) at the 3′ end.

DNA molecules are known to be poor conductors. To improve conductivity of nanodevices comprising DNA, metal ions may be attached or adsorbed to the negatively charged backbone of the DNA. See e.g. Braun, E., et al. Nature 391:775-778; Richter, J., et al. (2000) Adv. Mater., 12(7):507-510; Ford, W. E., et al. (2001) Nanoparticles 13(23):1793-1797; Ciacchi, L. C., et al. (2003) Nanotechnology 14:840-848; and Monson, C. F., et al. (2003) Nano Lett. 3(3):359-363, which are herein incorporated by reference.

Dual DNA functionalized nanocrystals and SWCNTs and side-wall DNA functionalized SWCNTs may be used in “drop-in” CNT-CNT-CNT and CNT-NC-CNT transistors via electron beam lithography. See Kamaras, K., et al. (2003) Science 301:1501, which is herein incorporated by reference. The nanocrystals and SWCNT may be functionalized using methods know in the art or by the following general steps:

DNA that has two different restriction sites that can be reliably cleaved with the use of a different restriction enzyme is selected. One of the ends of the DNA is functionalized with a thiol group so that the DNA can be anchored to nanofabricated gold pads (20 nm×20 nm pads via electron beam lithography) on a Si surface. The gold pads are kept small to limit the number of DNA to a minimum. Also the pads are separated from one another by 200 nm on either side so as to avoid interaction between neighboring DNA. This cleaving leaves reactive ends that can be annealed with the complimentary bases. Once the SAM is formed a suitable restriction enzyme is used to cleave the DNA at the other restriction site. The substrate is thoroughly rinsed with deionized water to wash off the cut segment of the DNA.

The CNTs are then independently functionalized with DNA on its either ends using methods known in the art. The CNTs used are preferably very short tubes as small as about 20 nm to about 50 nm. The DNA is selected in such a way that it has amine functionality on one side and a restriction site along which when cleaved leaves out a reactive end that recognizes and anneal with the end of the DNA on the gold substrate.

Then the DNA on the CNT end and the DNA on the gold pad are annealed to leave a CNT vertically aligned on a gold pad. The functionalization is performed at the sidewalls and so out sidewalls still maintain their hydrophobic property. The CNTs are preferably short of the order of about 40 nm so that the CNTs align vertical on the tiny gold pads on the hydrophobic Silicon dioxide surface.

Two different DNAs may be introduced on the surface of the nanocrystal using methods known in the art. Preferably, the two different DNAs on the surface of the nanocrystals have different restriction sites, which may be cleaved by specific restriction enzymes.

The dual functionalized CNTs and nanocrystals may be used to form a basic building block for CNT-CNT-CNT and CNT-NC-CNT transistor structures. Generally, one of the restriction enzymes may be used to cleave one type of the DNA leaving the other type unaffected. This active end can be annealed with a CNT modified with a suitable DNA that would upon cleaving readily recognize the active ends on the nanocrystals to provide a CNT-NC assembly via DNA on a gold pad. DNA-CNT-DNA complexes with active sticky ends can be made to anneal with the other sticky ends on the nanocrystals to provide a CNT-NC-CNT on a gold substrate. Then the DNA directly tethered to the gold pad is cleaved at the restriction site to free the CNT- NC-CNT structure from the gold pad. In this structure, the two symmetrical CNTs serve as the source and drain, and the central nanocrystal serves as the gate for the field effect transistor structure. For the CNT-CNT-CNT configuration, the nanocrystal is replaced with a SWNT and only a mild functionalization procedure will be followed in order to just minimally perturb the pi-bond structure of the SWNT. The transistor structures obtained may be located on e-beam patterned substrates and contacts to the source, drain and gate will be made via lift-off patterning known in the art.

In some nanodevices, the SWCNTs and nanocrystals may be triple functionalized for synthesizing fully biological self assembled transistor structures. Generally, following the last step from CNT-NC-CNT and CNT-CNT-CNT synthesis as previously described, the second type of DNA is cleaved using a specific restriction enzyme and then annealed with CNTs functionalized with DNA cleaved separately to produce sticky ends on the CNT that will recognize the sticky ends on the nanocrystal. Similarly, the nanocrystals may be replaced with a SWNT to synthesize CNT-CNT-CNT structures. In preferred embodiments, the source and drain connections utilize metallized DNA, and the gate connections utilize non-metallized DNA, to realize a gate dielectric for field effect transistor operation. The sizes of the molecular components of our proposed devices may be controlled by using CNTs as the active channel and as the gate electrode in FET devices. Using CNTs as the gate material allows one to control the electronic characteristics of the channel-gate coupling using methodologies know in the art for the chemical modifications of CNTs.

Diameter control during the growth has been established to be a direct function of the initial catalyst particle size in the CVD process, whereas in the EA method, the diameter distribution is a complex function of the bimetallic ratio of the catalysts and the growth parameters. The lengths of the carbon nanotubes may be controlled in the CVD process by the growth duration. The EA method to grow SWCNTs in the bulk scale may be used and methods known in the art to process these materials into very high purity carbon nanotubes may be used. Size exclusion based chromatographic techniques known in the art may be used for short SWCNTs in order to obtain size control in the eluting material. Preferably, soft oxidation followed by chromatographic and reactive ion etching methods known in the art to cut CNTs are used to produce submicrometer SWCNTs with narrow length distributions on a substrate.

To the extent necessary to understand or complete the disclosure of the present invention, all publications, patents, and patent applications mentioned herein are expressly incorporated by reference therein to the same extent as though each were individually so incorporated.

Having thus described exemplary embodiments of the present invention, it should be noted by those skilled in the art that the within disclosures are exemplary only and that various other alternatives, adaptations, and modifications may be made within the scope of the present invention. Accordingly, the present invention is not limited to the specific embodiments as illustrated herein, but is only limited by the following claims.

1. A heterojunction comprising at least one carbon nanotube and at least one nanostructure connected, immobilized, attached, or affixed thereto.

2. The heterojunction of claim 1, wherein the carbon nanotube is a single walled carbon nanotube having a length of about 20 nm to about 2000 nm.

3. The heterojunction of claim 1, wherein the carbon nanotube is a multi-walled carbon nanotube having a length of about 40 nm to about 4000 nm.

4. The heterojunction of claim 1, wherein the nanostructure is a quantum dot or a quantum cluster comprising a plurality of quantum dots.

5. The heterojunction of claim 4, wherein the quantum dot is ZnS capped CdSe, CdSe, or TiO₂.

6. The heterojunction of claim 4, wherein the quantum dot comprises a CdSe core and a ZnS shell.

7. The heterojunction of claim 1, which comprises one carbon nanotube having one nanostructure connected, immobilized, attached, or affixed to one end of the carbon nanotube.

8. The heterojunction of claim 1, which comprises one carbon nanotube having two nanostructures connected, immobilized, attached, or affixed to each end of the carbon nanotube.

9. The heterojunction of claim 1, which comprises at least two carbon nanotubes having a nanostructures connected, immobilized, attached, or affixed to one end of each of the carbon nanotubes.

10. A method for making the heterojunction of claim 1, which comprises
oxidizing the ends of the carbon nanotube,
placing at least one amine group on the nanostructure, and
coupling at least one end of the carbon nanotube with the nanostructure.

11. The method of claim 10, wherein oxidizing the ends of the carbon nanotube comprises refluxing the carbon nanotube in an acid.

12. The method of claim 11, wherein the acid is nitric acid.

13. The method of claim 10, wherein the nanostructure has a ZnS shell or coating and placing at least one amine group on the nanostructure comprises reacting the nanostructure with 2-aminoethanethiolhydrochloride.

14. The method of claim 10, wherein coupling the end of the carbon nanotube with the nanostructure comprises adding 1-ethyl-3-(3-dimethylaminopropyl)carbodiimide HCL in the presence of N-hydroxysuccinimide to form a sulfosuccinimidyl intermediate that is capable of forming an amide bond with the amine group on the nanostructure.

15. A nanodevice which comprises the heterojunction of claim 1.

16. The nanodevice of claim 15, and further comprising at least one nanostructure selected from the group consisting of photoactive molecules, photonic molecules, inorganic ions, inorganic molecules, magnetic ions, magnetic molecules, metallic ions, metallic molecules, metallic colloids, metal oxide molecules, polymers, aptamers, haptens, radioactive molecules, fluorophores, chromophores, chemiluminescent molecules, nanowires, nanofibers, quantum dots, nucleotides, nucleic acid molecules, polynucleotides, amino acids, peptides, polypeptides, proteins, and peptide nucleic acids.

17. The nanodevice of claim 15, wherein the nanodevice is a transistor, a light emitting diode, an inverter, a resistors, a capacitors, an interconnect, or a biosensor.
